(19) United States
(12) Patent Application Publication
(10) Pub. No.: US 2025/0362339 A1
(43) Pub. Date: Nov. 27, 2025

(54) SEMICONDUCTOR TEST APPARATUS

(71) Applicant: Okins Electronics Co., Ltd, Uiwang-si (KR)

(72) Inventors: Jin Kook Jun, Gyeonggi-do (KR); Chan Ho Lee, Gyeonggi-do (KR); Yong Kwan Lee, Incheon (KR)

(21) Appl. No.: 19/215,482

(22) Filed: May 22, 2025

(30) Foreign Application Priority Data
May 22, 2024 (KR) 10-2024-0066290

(51) Int. Cl. G01R 31/28; G01R 1/04

(52) U.S. Cl. CPC G01R 31/2863; G01R 1/0416

(57) ABSTRACT

A semiconductor test apparatus is disclosed. The semiconductor test apparatus according to an aspect of the present disclosure may include a housing; a substrate disposed on a lower side of the housing; a plurality of contact pins mounted on the substrate; a soldering part configured to fix the plurality of contact pins to the substrate; and a cover part configured to surround the soldering part.

### CROSS-REFERENCE TO RELATED APPLICATION(S)

This application claims priority to and the benefit of Korean Patent Application No. 10-2024-0066290, filed on May 22, 2024, the disclosure of which is incorporated herein by reference in its entirety.

### TECHNICAL FIELD

The present disclosure relates to a semiconductor test apparatus, and more specifically to a semiconductor test apparatus for improving the bonding strength of a plurality of contact pins.

### RELATED ART

Generally, surface-mount semiconductor devices (SMT), such as IC devices or IC packages, are made of Land Grid Array (LGA), Ball Grid Array (BGA), Chip Sized Package (CSP) types and the like, and they undergo a burn-in test to confirm reliability before being shipped to customers.

Burn-in test refers to a process of determining whether a semiconductor device satisfies conditions when a temperature and voltage that are higher than normal operating conditions are applied to the semiconductor device before it is applied to the corresponding electronic device as described above. The semiconductor device as described above is mounted on a burn-in test socket and undergoes a burn-in test before being shipped to the customer.

In the case of a conventional burn-in test socket, it includes a base on which a semiconductor device is mounted, a cover that is movably coupled to the base, a contact complex having a plurality of contact pins and inserted into the base, and a latch that moves to an open and support position according to the up-and-down movement of the cover. The ends of contact pins supported by the contact complex are electrically connected to a Device under Test (DUT) board through soldering to test the performance of the semiconductor device.

The contact pins of wire or pin type exposed from the test socket are connected to a test device through electrodes of the DUT board, and the electrical properties of the semiconductor device are tested. The contact pins and the electrodes of the DUT board must be stably contacted, and the contact resistance must be small. In addition, the contact pins must not be deformed despite repeated burn-in tests, and the electrodes of the PCB test substrate of the test board must not be damaged.

The contact pins are assembled as a whole through the contact complex, and are also bonded as a whole through the soldering process with the DUT board. However, if foreign substances are introduced into the soldering process area, there is a concern that errors may occur in the test results of the semiconductor device.

In addition, during the test process of the semiconductor device, there is a concern that the soldering area may have a weakened bonding strength due to heat, thereby causing the contact pins to separate from the DUT board.

### SUMMARY

The present disclosure has been devised to solve the above problems, and an object of the present disclosure is to provide a semiconductor test apparatus that stably maintains a plurality of contact pins in a state of being bonded to a substrate.

The problems of the present disclosure are not limited to the problems mentioned above, and other problems that are not mentioned will be clearly understood by those skilled in the art to which the present disclosure pertains from the description below.

According to an aspect of the present disclosure, provided is a semiconductor test apparatus, including: a housing; a substrate disposed on a lower side of the housing; a plurality of contact pins mounted on the substrate; a soldering part configured to fix the plurality of contact pins to the substrate; and a cover part configured to surround the soldering part.

In this case, a material of the cover part may be more heat resistant than a material of the soldering part.

In this case, a material of the cover part may be epoxy resin.

In this case, a width of the plurality of contact pins is formed as a first length, the soldering part may wrap an outer side surface of the plurality of contact pins with a second length that is smaller than the first length from an outer side surface of the plurality of contact pins, and the cover part may wrap an outer side surface of the soldering part with a third length that is equal to the first length from an outer side surface of the soldering part.

In this case, a height of the soldering part may be equal to the first length, and a height of the cover part may be longer than the first length.

In this case, the semiconductor test apparatus may further include a support part having a plurality of support holes through which some of the plurality of contact pins pass.

In this case, the support part may include a plurality of first support members that are disposed to be spaced apart from each other, and are formed parallel to each other; and a plurality of second support members that extend obliquely from the plurality of first support members, wherein the plurality of contact pins may be moved through the plurality of second support members and come into contact between the plurality of first support members.

In this case, the plurality of second support members may be spaced apart from each other as the plurality of second support members move in a first direction.

According to the above configuration, the semiconductor test apparatus according to an embodiment of the present disclosure has an advantage in that since the cover part surrounds the soldering part, even if the soldering part melts due to heat, the cover part stably supports the soldering part, thereby stably maintaining a state in which a plurality of contact pins are bonded to the substrate.

### BRIEF DESCRIPTION OF THE DRAWINGS

FIG. 1 is a perspective view showing the appearance of a semiconductor test apparatus according to an embodiment of the present disclosure.

FIG. 2 is an exploded perspective view showing a semiconductor test apparatus according to an embodiment of the present disclosure.

FIG. 3 is a perspective view showing a plurality of contact pins and a substrate of a semiconductor test apparatus according to an embodiment of the present disclosure.

FIG. 4 is a cross-sectional view showing one of a plurality of contact pins, a soldering part and a cover part of a semiconductor test apparatus according to an embodiment of the present disclosure.

FIG. 5 is a cross-sectional view showing the inside of a semiconductor test apparatus according to an embodiment of the present disclosure.

FIG. 6 is a cross-sectional view showing a support part and a plurality of contact pins of a semiconductor test apparatus according to an embodiment of the present disclosure separated from each other.

FIG. 7 is a cross-sectional view showing a plurality of contact pins penetrating a support part of a semiconductor test apparatus according to an embodiment of the present disclosure.

### DETAILED DESCRIPTION OF THE EMBODIMENTS

Hereinafter, with reference to the attached drawings, embodiments of the present disclosure will be described in detail so that those skilled in the art can easily practice the present disclosure. The present disclosure may be implemented in various different forms and is not limited to the embodiments described herein. In order to clearly describe the present disclosure, parts that are not related to the description in the drawings have been omitted, and the same reference numerals have been assigned to identical or similar components throughout the specification.

The words and terms used in the present specification and claims should not be interpreted as having limited or conventional meanings, but should be interpreted as meanings and concepts that conform to the technical idea of the present disclosure according to the principle that the inventor can define terms and concepts in order to explain his or her invention in the best way.

Therefore, the embodiments described in the present specification and the configurations illustrated in the drawings correspond to a preferred embodiment of the present disclosure, and do not represent all of the technical ideas of the present disclosure, and thus, the corresponding configuration may have various equivalents and modified examples that can replace the same at the time of filing the present disclosure.

In the present specification, terms such as “include” or “have” are intended to describe the presence of a feature, number, step, operation, component, part or combination thereof described in the specification, and should be understood as not excluding in advance the possibility of the presence or addition of one or more other features, numbers, steps, operations, components, parts or combinations thereof.

When a component is “in front”, “behind”, “above” or “below” another component, unless there are special circumstances, it includes not only a case where it is directly in contact with the other component and is arranged “in front”, “behind”, “above” or “below” the same, but also a case where another component is arranged in between. In addition, when a component is “connected” to another component, unless there are special circumstances, it includes a case where they are directly connected to each other as well as a case where they are indirectly connected to each other.

Hereinafter, the semiconductor test apparatus according to an embodiment of the present disclosure will be described with reference to the drawings.

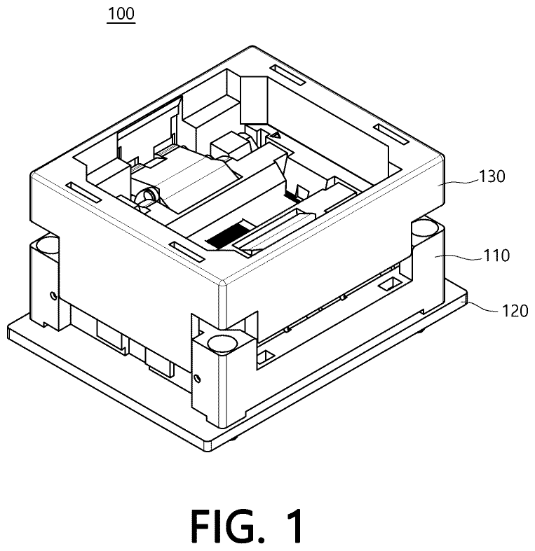

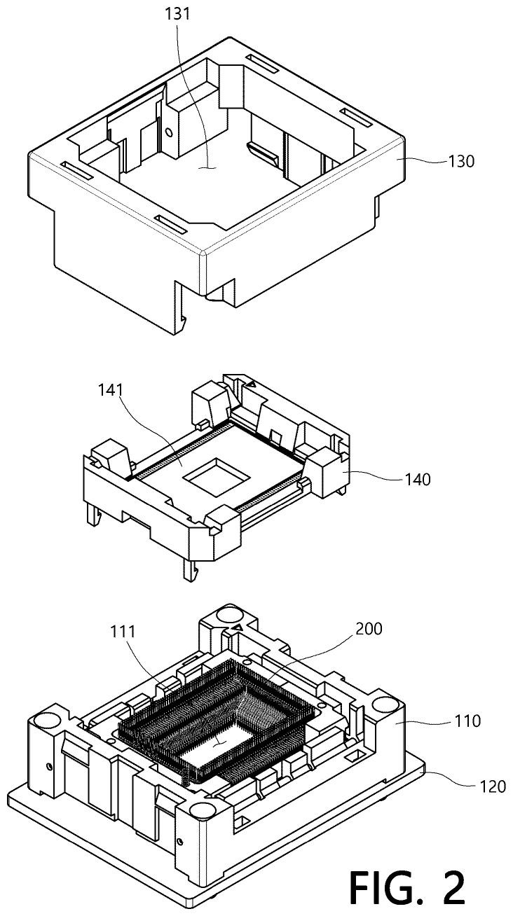

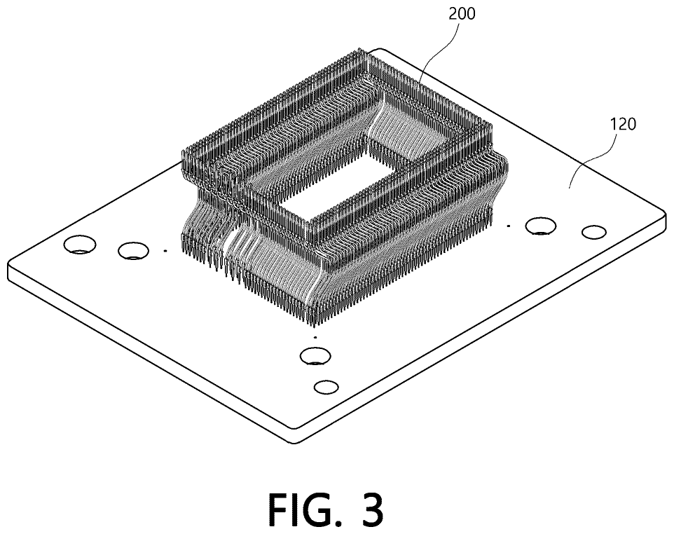

FIG. 1 is a perspective view showing the appearance of a semiconductor test apparatus according to an embodiment of the present disclosure, FIG. 2 is an exploded perspective view showing a semiconductor test apparatus according to an embodiment of the present disclosure, and FIG. 3 is a perspective view showing a plurality of contact pins and a substrate of a semiconductor test apparatus according to an embodiment of the present disclosure.

Referring to FIGS. 1 to 3, the semiconductor test apparatus 100 according to an embodiment of the present disclosure includes a housing 110, a substrate 120, a cover part 130, a plurality of contact pins 200 and a support part 140.

The housing 110 is formed to accommodate a semiconductor for testing (not shown). In addition, the upper side of the housing 110 may be formed to have an open structure such that the semiconductor for testing can be accommodated by moving from the upper side to the lower side of the housing 110.

In addition, the housing 110 may be made of a metal material. However, the housing 110 is not limited to being made of a metal material, and may be made of various materials such as a rigid plastic.

The substrate 120 is disposed on a lower side of the housing 110. In addition, the substrate 120 may be coupled to the housing 110. In this case, the substrate 120 may be provided with a control unit (not shown) for testing the electrical properties of the semiconductor for testing.

In addition, according to various embodiments of the present disclosure, the control unit may not be provided on the substrate 120 but may be provided separately. In addition, the substrate 120 may be electrically connected to the control unit provided separately.

The cover part 130 is disposed on an upper side of the housing 110. In addition, when the semiconductor test apparatus 100 is not used, the cover part 130 may include a latch (not shown) that closes an upper side of the housing 110. Accordingly, when the latch closes the upper side of the housing 110, foreign substances are prevented from entering from the upper side of the housing 110.

The plurality of contact pins 200 are mounted on the substrate 120 as shown in FIG. 3. In this case, the plurality of contact pins 200 are bonded to the substrate 120 using laser welding. Specifically, a laser device (not shown) irradiates a lead arranged around the plurality of contact pins 200 with a laser to bond the lead to the substrate 120.

Then, the lead wraps around a portion of the plurality of contact pins 200 and fixes the plurality of contact pins 200 to the substrate 120. Herein, the lead wrapping around a portion of the plurality of contact pins 200 will be referred to as a soldering part.

In addition, the soldering part is not limited to being made of a lead material, and may be made of various materials having electrical conductivity.

The support part 140 is disposed between the housing 110 and the cover part 130. In addition, the support part 140 is supported by the housing 110. In addition, the support part 140 is disposed on an upper side of the plurality of contact pins 200. In addition, a plurality of support holes 143 are formed in the support part 140 through which some of the plurality of contact pins 200 pass.

In addition, the plurality of support holes 143 are formed at positions corresponding to the plurality of contact pins 200. In addition, when the support part 140 is settled on the upper side of the housing 110, some of the plurality of contact pins 200 protrude from the upper side of the support part 140 through the plurality of support holes 143.

In addition, when a semiconductor for testing is accommodated in the housing 110, the plurality of contact pins 200 are electrically connected to the terminals of the semiconductor for testing. In this way, the support part 140 stably supports the plurality of contact pins 200 in the process of repeatedly contacting the semiconductor for testing with the plurality of contact pins 200.

Meanwhile, the content for preventing the soldering part 210 from losing bonding strength due to heat during the semiconductor testing process will be described below with reference to the drawings.

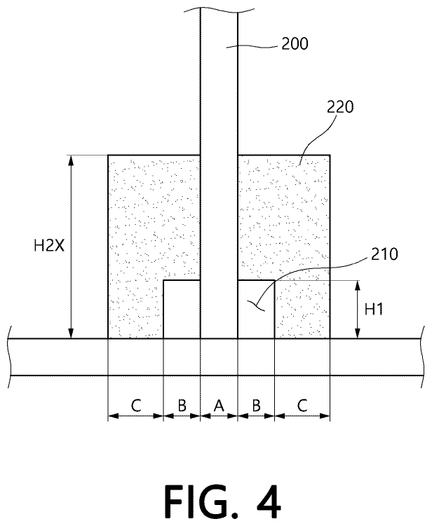

FIG. 4 is a cross-sectional view showing one of a plurality of contact pins, a soldering part and a cover part of a semiconductor test apparatus according to an embodiment of the present disclosure.

Referring to FIG. 4, the semiconductor test apparatus according to an embodiment of the present disclosure includes a cover part 220 that surrounds the soldering part 210. In addition, the soldering part 210 and the cover part 220 are configured in plurality to correspond to the plurality of contact pins 200, but for the convenience of explanation, the plurality of contact pins 200 will be referred to as contact pins 200.

First of all, the soldering part 210 is formed to surround an outer side of the contact pin 200 bonded to the substrate 120. In addition, the soldering part 210 electrically connects the substrate 120 and the contact pin 200 while bonding the contact pin 200 so as to be mounted on the substrate 120.

The cover part 220 is formed to surround the soldering part 210. In addition, the material of the cover part 220 has stronger heat resistance than the material of the soldering part 210. That is, the melting point of the material of the cover part 220 is higher than the melting point of the material of the soldering part 210. For example, the material of the cover part 220 may be epoxy resin. However, the cover part 220 is not limited to being made of epoxy resin, and may be made of various materials having a melting point higher than the material of the soldering part 210.

In this way, even if the soldering part 210 melts due to heat during a semiconductor test process, the contact pin 200 is prevented from being separated from the substrate 120 as the cover part 220 stably supports the soldering part 210.

In addition, as the cover part 220 is formed to surround the soldering part 210, it prevents external foreign substances from coming into contact with the soldering part 210, thereby preventing a short circuit caused by foreign substances during a semiconductor test process.

In addition, according to an embodiment of the present disclosure, the width of the contact pin is formed as a first length (A).

In addition, the soldering part 210 wraps an outer side surface of the contact pin 200 with a second length (B) that is smaller than the first length from the outer side surface of the contact pin 200. For example, the second length (B) is half of the first length (A). Accordingly, the soldering part 210 prevents a gap between the plurality of contact pins 200 from increasing such that the cover part 220 is disposed between the plurality of contact pins 200.

In addition, the cover part 220 wraps an outer side surface of the soldering part with a third length (C) that is equal to the first length from the outer side surface of the soldering part 210. That is, the third length (C) may be twice the second length (B). Accordingly, when the soldering part 210 melts due to heat, even if a portion of the cover part 220 adjacent to the soldering part 210 melts together with the soldering part 210, the cover part 220 may stably cover the soldering part 210.

In addition, according to an embodiment of the present disclosure, the height (H1) of the soldering part is formed to be the same length as the first length (A).

In addition, the height (H2) of the cover part may be longer than the first length (A). For example, the height (H2) of the cover part may be twice the first length (A).

In addition, among the portions of the cover part 220 adjacent to the soldering part 210, when the soldering part 210 melts due to heat, the upper side portion of the cover part 220 may melt more than a side surface portion of the cover part 220. Accordingly, when the soldering part 210 melts due to heat, even if the upper side portion of part of the cover part 220 adjacent to the soldering part 210 melts together with the soldering part 210, the cover part 220 may stably cover the soldering part 210.

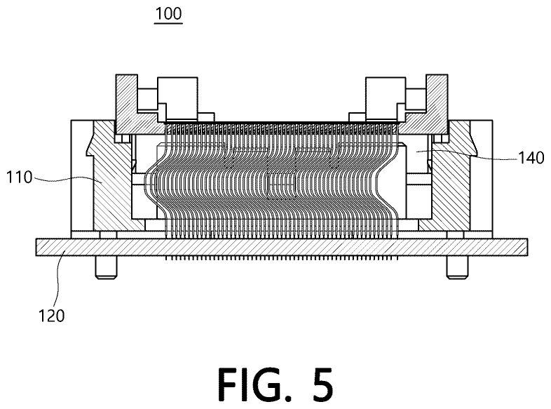

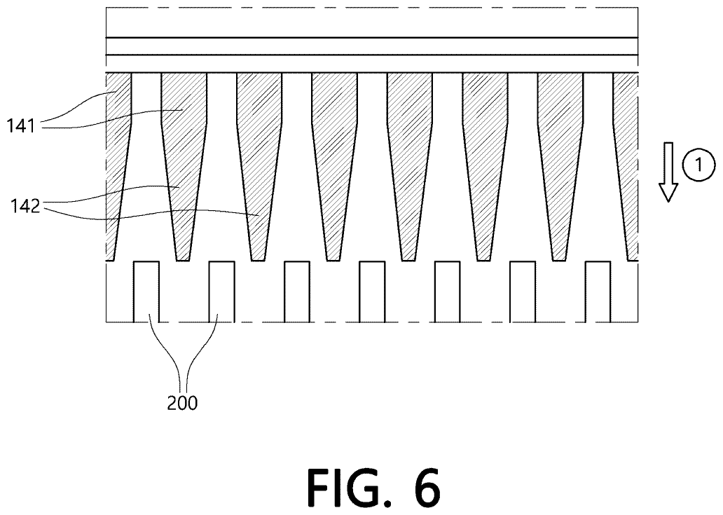

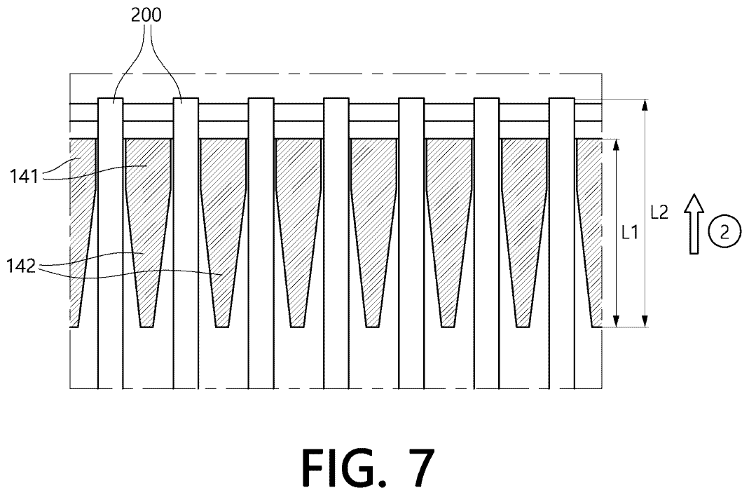

FIG. 5 is a cross-sectional view showing the inside of a semiconductor test apparatus according to an embodiment of the present disclosure, FIG. 6 is a cross-sectional view showing a support part and a plurality of contact pins of a semiconductor test apparatus according to an embodiment of the present disclosure separated from each other, and FIG. 7 is a cross-sectional view showing a plurality of contact pins penetrating a support part of a semiconductor test apparatus according to an embodiment of the present disclosure.

First of all, as shown in FIG. 2 and FIG. 5, the support part 140 moves from the upper side to the lower side of the plurality of contact pins 200 to insert the plurality of contact pins 200 into the support holes 143. In this case, there is a problem in that the plurality of contact pins 200 are damaged during the process of being inserted into the support holes 143.

In order to solve this problem, as shown in FIG. 6 and FIG. 7, the support part 140 of the semiconductor test apparatus according to an embodiment of the present disclosure includes a plurality of first support members 141 and a plurality of second support members 142.

The plurality of first support members 141 are disposed to be spaced apart from each other, and are formed parallel to each other. In this case, a gap between the plurality of first support members 141 may be the same as the outer diameter of the plurality of contact pins 200.

The plurality of second support members 142 extend obliquely from the plurality of first support members 141. In this case, the outer diameter of the plurality of second support members 142 becomes smaller as it moves away from the plurality of first support members 141.

In addition, a direction in which the plurality of second support members 142 move away from the plurality of first support members 141 is referred to as a first direction (1).

In addition, the plurality of second support members 142 become further apart from each other as they move in the first direction ((1).

In addition, as shown in FIG. 7, the plurality of contact pins 200 are relatively moved in a second direction ((2) that is opposite to the first direction ((1)) as the support part 140 is moved in the first direction (1).

That is, the plurality of contact pins 200 are moved through the plurality of second support members 142 and come into contact between the plurality of first support members 141.

Accordingly, the plurality of contact pins 200 are stably guided by the plurality of second support members 142 in the process of moving in the second direction ((2)), thereby preventing the plurality of contact pins 200 from being damaged by the plurality of second support members 142.

In addition, according to an embodiment of the present disclosure, the sum (L1) of the length of the first support member 141 and the length of the second support member 142 is smaller than a distance (L2) by which the plurality of contact pins 200 are relatively moved in the second direction (2).

Accordingly, the plurality of first support members 141 and the plurality of second support members 142 stably guide the movement of the plurality of contact pins 200 while minimizing the contact of the plurality of contact pins 200, thereby preventing the plurality of contact pins 200 from being damaged.

Although the embodiments of the present disclosure have been described, the spirit of the present disclosure is not limited to the embodiments presented in this specification, and those skilled in the art who understand the spirit of the present disclosure will be able to easily propose other embodiments by modifying, changing, deleting or adding components within the scope of the same spirit, but this will also be considered to fall within the spirit scope of the present disclosure.

What is claimed is:

1. A semiconductor test apparatus, comprising:
a housing;
a substrate disposed on a lower side of the housing;
a plurality of contact pins mounted on the substrate;
a soldering part configured to fix the plurality of contact pins to the substrate; and
a cover part configured to surround the soldering part.

2. The semiconductor test apparatus of claim 1, wherein a material of the cover part is more heat resistant than a material of the soldering part.

3. The semiconductor test apparatus of claim 1, wherein a material of the cover part is epoxy resin.

4. The semiconductor test apparatus of claim 1, wherein a width of the plurality of contact pins is formed as a first length,
wherein the soldering part wraps an outer side surface of the plurality of contact pins with a second length that is smaller than the first length from an outer side surface of the plurality of contact pins, and
wherein the cover part wraps an outer side surface of the soldering part with a third length that is equal to the first length from an outer side surface of the soldering part.

5. The semiconductor test apparatus of claim 4, wherein a height of the soldering part is equal to the first length, and
wherein a height of the cover part is longer than the first length.

6. The semiconductor test apparatus of claim 1, further comprising:
a support part having a plurality of support holes through which some of the plurality of contact pins pass.

7. The semiconductor test apparatus of claim 6, wherein the support part comprises:
a plurality of first support members that are disposed to be spaced apart from each other, and are formed parallel to each other; and
a plurality of second support members that extend obliquely from the plurality of first support members,
wherein the plurality of contact pins are moved through the plurality of second support members and come into contact between the plurality of first support members.

8. The semiconductor test apparatus of claim 7, wherein the plurality of second support members become further apart from each other as the plurality of second support members move in a first direction.
